(19) United States
(12) Patent Application Publication
(10) Pub. No.: US 2020/0220290 A1
(43) Pub. Date: Jul. 9, 2020

(54) ELECTRONIC DEVICE AND HOST THEREOF

(71) Applicant: ASUSTEK COMPUTER INC., TAIPEI (TW)

(72) Inventors: Wen-Yen CHEN, TAIPEI (TW); Chih-Shien LIN, TAIPEI (TW); Ming-Hung CHUNG, TAIPEI (TW); Shao-Lung CHANG, TAIPEI (TW)

(21) Appl. No.: 16/735,142

(22) Filed: Jan. 6, 2020

(30) Foreign Application Priority Data
Jan. 4, 2019 (TW) 108200132

(51) Int. Cl. H01R 13/04; H04N 21/4363

(52) U.S. Cl. CPC H01R 13/04; H04N 21/43635

(57) ABSTRACT

An electronic device includes a host and an apparatus. The host includes a controller, a signal transmission unit, and a connector. The controller is configured to generate a control signal. The signal transmission unit is electrically connected to the controller, to receive the control signal and generate a carrier to carry the control signal. The connector is configured to connect to the apparatus. The connector includes at least one of a power pin and a ground pin to transmit the carrier.

### CROSS-REFERENCE TO RELATED APPLICATION

This application claims the priority benefit of Taiwan Application Serial No. 108200132, filed on Jan. 4, 2019. The entirety of the above-mentioned patent application is hereby incorporated by reference herein and made a part of specification.

### BACKGROUND OF THE INVENTION

### Field of the Invention

The disclosure relates to an electronic device and a host thereof.

### Description of the Related Art

Limited by a hardware architecture (especially a connector), the quantity of signals transmitted between a conventional host and a device is limited. Currently, a mainboard is connected to a fan via four pins. The four pins are a power supply pin (VDD), a ground pin (GND), a pulse width modulation control pin (PWM), and a feedback signal pin (FG). The mainboard controls the fan to rotate only by using the PWM, and obtains rotation speed information of the fan by using the FG.

### BRIEF SUMMARY OF THE INVENTION

The disclosure provides an electronic device. The electronic device includes a host and an apparatus. The host includes a host controller, a first signal transmission unit, and a host connector. The host controller is configured to generate a control signal. The first signal transmission unit is electrically connected to the host controller to receive the control signal, and used for generating a first carrier to carry the control signal.

The host connector is electrically connected to the first signal transmission unit. The host connector includes at least one of a power pin and a ground pin, to transmit the first carrier. The apparatus includes an apparatus connector and a second signal transmission unit.

The apparatus connector is connected to the host connector to receive the first carrier. The second signal transmission unit is electrically connected to the apparatus connector to receive the first carrier, and the first carrier obtains the control signal from the host controller to control the apparatus.

The disclosure further provides a host, configured to control an apparatus. The host includes a controller, a signal transmission unit, and a connector. The controller is configured to generate a control signal. The signal transmission unit is electrically connected to the controller, to receive the control signal, and generate a carrier to carry the control signal. The connector is configured to connect the apparatus. The connector includes at least one of a power pin and a ground pin, to transmit the carrier.

The electronic device and the host thereof provided in the disclosure are applicable to an existing hardware architecture, especially a connector part. An additional signal is transmitted by using an existing pin to increase signal transmission paths between the host and the apparatus, and further to provide more diversified control selections for a user.

Specific embodiments used in the disclosure are further described by using the following embodiments and figures.

### BRIEF DESCRIPTION OF THE DRAWINGS

FIG. 1 is a schematic diagram of a first embodiment of an electronic device of the disclosure.

FIG. 2 is a schematic diagram of a second embodiment of an electronic device of the disclosure.

FIG. 3 is a schematic diagram of a third embodiment of an electronic device of the disclosure.

### DETAILED DESCRIPTION OF THE EMBODIMENTS

Specific embodiments of the disclosure are further described below with reference to schematic drawings. Advantages and features of the disclosure are clearer according to the following descriptions and claims. It should be noted that the drawings, which are in excessively simplified forms and all not drawn to accurate scale, are merely used for facilitating a clear understanding of the embodiments of the disclosure.

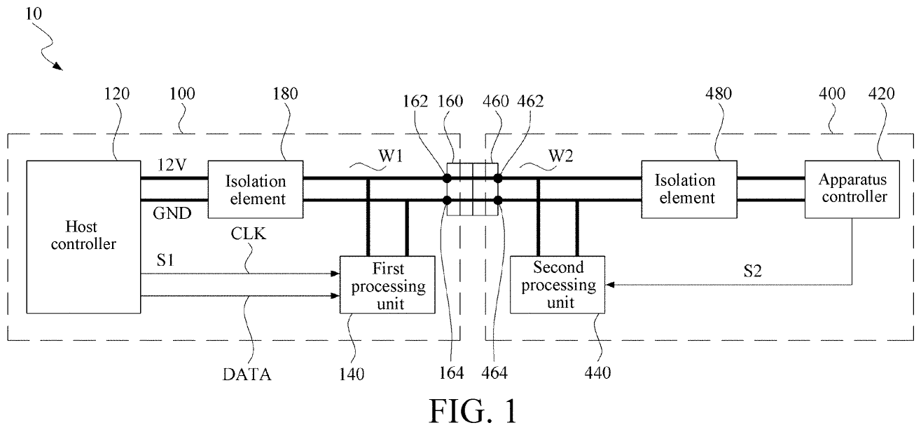

FIG. 1 is a schematic diagram of a first embodiment of an electronic device 10 of the disclosure. The electronic device 10 includes a host 100 and an apparatus. In this embodiment, the apparatus is a fan 400, and is configured to perform heat dissipation for the electronic device but is not limited thereto. The apparatus is connected to the host 100 by using a connector. The apparatus is controlled by the host, such as a USB flash drive, a hard disk, a wireless network interface card, an RGB strip light, an ARGB strip light, a water cooling fan, an air cooling fan, a power supply unit, a graphics card, an audio device, a memory, or a central processing unit (CPU). A connection interface of the apparatus is an HDMI, a Display port, a D-sub, or a USB type-C.

In an embodiment, the host 100 is a mainboard, but is not limited thereto. The host 100 is an electronic device including a connector to connect a peripheral apparatus to extend functions. The host 100 is a desktop computer, a notebook computer, or a mobile phone.

As shown in the figure, the host 100 includes a host controller 120, a first signal transmission unit 140, a host connector 160, and an isolation element 180. The host controller 120 is configured to generate a control signal S1 to control the fan 400. In an embodiment, the control signal S1 is a fan rotation control signal, a light emitting diode control signal, or the like. In an embodiment, the host controller 120 is a fan controller.

The first signal transmission unit 140 is electrically connected to the host controller 120 to receive the control signal S1. In an embodiment, the control signal is a digital signal. As shown in the figure, the host controller 120 transmits the control signal S1 to the first signal transmission unit 140 by using a communications protocol through a frequency transmission line CLK and a data transmission line DATA. The communications protocol is a communications protocol commonly applied in a computer system, such as an SMBUS communications protocol, an I2C communications protocol, or an SPI communications protocol.

After receiving the control signal S1, the first signal transmission unit 140 generates a first carrier W1 to carry the control signal S1. A technology for carrying a digital signal by using a carrier in a modulation manner is known in the field, and details are not described herein again. In an embodiment, the first signal transmission unit 140 is a modulation processing unit, but is not limited thereto. The first signal transmission unit 140 is a modulation/demodulation processing unit.

As shown in the figure, the host connector 160 is configured to connect the fan 400. The first signal transmission unit 140 is electrically connected to the host connector 160. In this embodiment, the host connector 160 is a fan connector. The fan connector includes a power pin 162 and a ground pin 164. The power pin 162 and the ground pin 164 are configured to provide electric power required for operating the fan 400.

In an embodiment, the power pin 162 is configured to provide a 12V power supply, and the ground pin 164 is a GND. In addition, the first signal transmission unit 140 transmits the first carrier W1 by using at least one of the power pin 162 and the ground pin 164. In this embodiment, the first signal transmission unit 140 transmits the first carrier W1 by using the power pin 162. However, it is not limited thereto. The first signal transmission unit 140 alternatively transmits the first carrier W1 by using the ground pin 164.

In an embodiment, the first signal transmission unit 140 alternatively generates two carriers to carry different control signals, and respectively transmits the two carriers by using the power pin 162 and the ground pin 164.

As shown in the figure, in an embodiment, in addition to providing the control signal S1 to the first signal transmission unit 140, the host controller 120 is further electrically connected to the host connector 160 to provide electric power required for operating the fan 400 and functions supported by hardware of the original host connector 160. In an embodiment, the host controller 120 provides electric power (for example, 12V) to drive the fan 400 by using the power pin 162. The host controller 120 controls the fan 400 to rotate by using a pulse width modulation control pin, and obtains rotation speed information of the fan 400 by using a feedback signal pin (not shown in the figure).

In an embodiment, by appropriately adjusting a frequency of the first carrier W1, the first signal transmission unit 140 transmits the first carrier W1 to the fan 400 by using the power pin 162 or the ground pin 164 to perform control while the host controller 120 provides electric power for the fan 400 by using the power pin 162 or the ground pin 164.

In an embodiment, the host 100 includes an isolation element 180 electrically connected to a rear end of the host connector 160. That is, the isolation element is disposed between the host connector 160 and the host controller 120, to isolate the first carrier W1 from affecting normal operation of an internal element of the host 100. In an embodiment, the isolation 180 is an inductor.

The fan 400 includes an apparatus connector 460, a second signal transmission unit 440, an apparatus controller 420, and an isolation element 480. The apparatus connector 460 is configured to connect the host connector 160 to receive the first carrier W1.

In an embodiment, the apparatus connector 460 is compatible with the host connector 160. In an embodiment, a quantity of pins and a function of the apparatus connector 460 are the same as a quantity of pins and a function of the host connector 160. Therefore, the first carrier W1 transmitted by using the power pin 162 or the ground pin 164 of the host connector 160 is received by a corresponding power pin 462 or a corresponding ground pin 464 of the apparatus connector 460.

The second signal transmission unit 440 is electrically connected to the apparatus connector 460 to receive the first carrier W1, and the first carrier W1 obtains the control signal S1 from the host controller 120. A technology for a carrier to obtain a digital signal carried in the carrier in a demodulation manner is known in the field, and details are thus omitted herein.

In an embodiment, the second signal transmission unit 440 is a demodulation processing unit but is not limited thereto. The second signal transmission unit 440 is also a modulation/demodulation processing unit.

The apparatus controller 420 is electrically connected to the second signal transmission unit 440 to receive the control signal S1 and control the fan 400 to operate.

As shown in the figure, the fan 400 includes an isolation element 480 electrically connected to the apparatus connector 460, to isolate the first carrier W1 from affecting normal operation of an internal element of the fan 400. In an embodiment, the isolation 480 is an inductor.

A direction of the control signal S1 described in the previous paragraphs is transmitted from the host 100 to the fan 400. However, it is not limited thereto. Referring to FIG. 1, in an embodiment, the apparatus controller 420 further generates an apparatus signal S2, such as a fan information signal or a fan status signal, to be provided to the host 100.

After receiving the apparatus signal S2, the second signal transmission unit 440 generates a second carrier W2 to carry the apparatus signal S2, and transmits the second carrier W2 to the host connector 160 by using the apparatus connector 460. In an embodiment, the second signal transmission unit 440 transmits the second carrier W2 to the host connector 160 by using at least one of the power pin 462 and the ground pin 464 of the apparatus connector 460.

After the first signal transmission unit 140 of the host 100 receives the second carrier W2 by using the host connector 160, the second carrier W2 obtains the apparatus signal S2 and transmits the apparatus signal back to the host controller 120 for subsequent processing.

In an embodiment, the host controller 120 displays the apparatus signal S2 in a display unit (not shown in the figure) for a user to examine. In an embodiment, when the apparatus signal S2 is a fan status signal, the host controller 120 displays a corresponding fan status in a display unit for a user to examine.

In an embodiment, the host controller 120 adjusts, based on the apparatus signal S2, the control signal S1 generated by the host controller 120 in a real-time manner. In an embodiment, when the apparatus signal S2 is rotation speed information of a fan, the host controller 120 adjusts, based on a rotation speed of the fan and an environmental temperature, the control signal S1 output by the host controller 120 to adjust a heat dissipation capability of the fan 400 in a real-time manner.

As described above, by using the electronic device 10 provided in the disclosure, the host 100 transmits the control signal S1 to the fan 400 by using at least one of the power pin 162 and the ground pin 164 of the host connector 160 to perform control, and the fan 400 obtains the apparatus signal S2 by using at least one of the power pin 162 and the ground pin 164 of the host connector 160. Similar to the aforesaid arrangement, more function selections can be provided for a user.

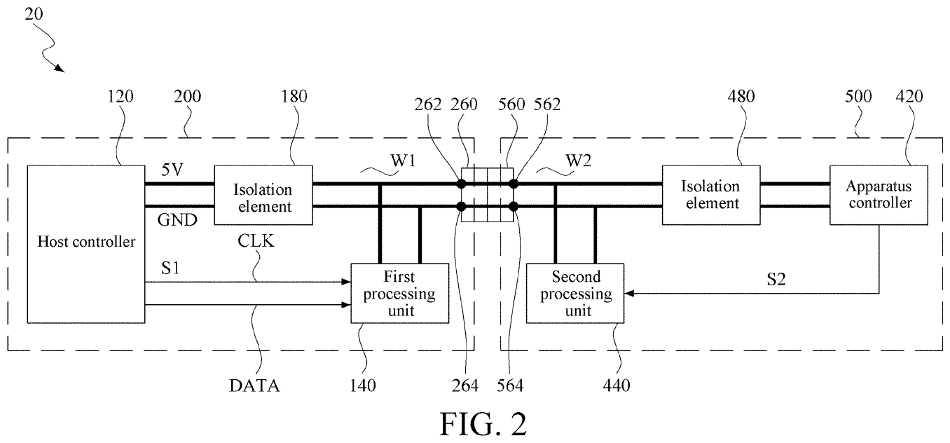

FIG. 2 is a schematic diagram of a second embodiment of an electronic device 20 of the disclosure. A major difference between this embodiment and the first embodiment lies in that a host 200 of this embodiment is connected to a universal serial bus (USB) apparatus 500, such as a USB storage apparatus or a USB interface network card. A host connector 260 is a USB connector. A corresponding apparatus connector 560 is a USB plug configured to insert into the host connector 260.

Compared with the host connector 160 in FIG. 1 (i.e., a fan connector), the host connector 260 of this embodiment further includes a power pin 262 and a ground pin 264 that are configured to connect a corresponding power pin 562 and a corresponding ground pin 564 of the apparatus connector 560, respectively. However, a voltage level of the power pin 262 is 5V, and is different from 12V in the first embodiment. Other hardware parts used for connecting the host 100 and the USB apparatus 500, and signal transmission manners are all similar to those in the first embodiment, and details are omitted herein.

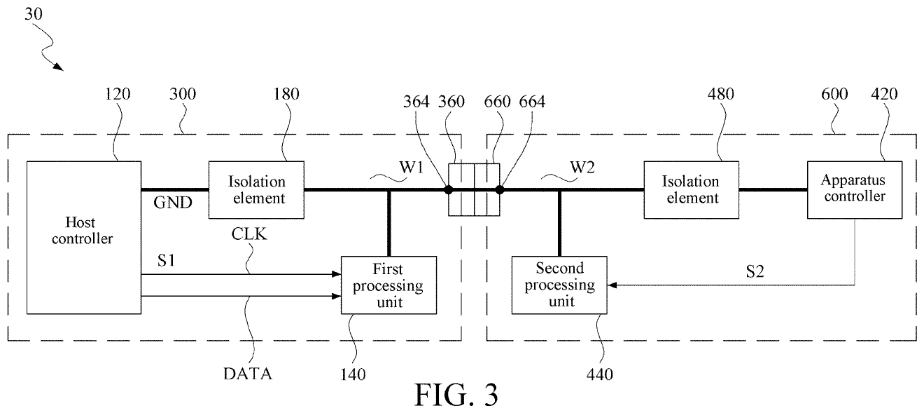

FIG. 3 is a schematic diagram of a third embodiment of an electronic device 30 of the disclosure. Compared with the embodiment in FIG. 1, the host 300 of this embodiment is connected to a serial advanced technology attachment (SATA) apparatus 600, such as an SATA hard disk. A host connector 360 is an SATA connector. An apparatus connector 660 is an SATA plug configured to insert into the host connector 360.

Compared with the host connector 160 in FIG. 1 (i.e., a fan connector), the host connector 360 of this embodiment includes a ground pin 364 connected to a corresponding ground pin 664 of the apparatus connector 660. The first carrier W1 generated by the first signal transmission unit 140 of the host and the second carrier W2 generated by the second signal transmission unit 440 of the SATA apparatus 600 are transmitted between the host 300 and the SATA apparatus 600 by using the ground pin 364. Other hardware parts used for connecting the host 300 and the apparatus 600, and signal transmission manners are all similar to those in the first embodiment, and details are omitted herein.

Compared with a conventional electronic device, the electronic device and the host thereof provided in the disclosure are applied to an existing hardware architecture, especially a connector part. An additional signal is transmitted by using an existing pin to increase signal transmission paths between the host and the apparatus, and further to provide more diversified control selections for a user.

The disclosure is disclosed through the foregoing embodiments; however, these embodiments are not intended to limit the disclosure. A person skilled in the art may make various variations and improvements without departing from the spirit and scope of the disclosure. Therefore, the protection scope of the disclosure shall be subject to the appended claims.

What is claimed is:

1. An electronic device, comprising:
a host, comprising:
a host controller, configured to generate a control signal;
a first signal transmission unit, electrically connected to the host controller, to receive the control signal, and to generate a first carrier to carry the control signal; and
a host connector, electrically connected to the first signal transmission unit, comprising at least one of a power pin and a ground pin, to transmit the first carrier; and
an apparatus, comprising:
an apparatus connector, connected to the host connector to receive the first carrier; and
a second signal transmission unit, electrically connected to the apparatus connector to receive the first carrier, wherein the first carrier obtains the control signal to control the apparatus.

2. The electronic device according to claim 1, wherein the host controller transmits the control signal to the first signal transmission unit by using a communications protocol.

3. The electronic device according to claim 2, wherein the communications protocol is an SMBUS communications protocol, an I2C communications protocol, or an SPI communications protocol.

4. The electronic device according to claim 1, wherein the host supplies power to the apparatus by using the power pin.

5. The electronic device according to claim 1, wherein the first signal transmission unit or the second signal transmission unit is a modulation/demodulation processing unit.

6. The electronic device according to claim 1, wherein the host connector is a fan connector, a universal serial bus (USB) connector, a serial advanced technology attachment (SATA) connector, an HDMI connector, a Display port connector, or a D-sub connector.

7. The electronic device according to claim 1, wherein the apparatus further comprises an apparatus controller configured to generate an apparatus signal, and the second signal transmission unit is electrically connected to the apparatus controller to receive the apparatus signal and generate a second carrier to carry the apparatus signal;
wherein the second signal transmission unit transmits the second carrier to the power pin or the ground pin of the host connector by using the apparatus connector; and
wherein the first signal transmission unit receives the second carrier, and the second carrier obtains the apparatus signal and transmits the apparatus signal back to the host controller.

8. The electronic device according to claim 1, wherein the control signal is a digital signal.

9. The electronic device according to claim 1, wherein the host further comprises an isolation element electrically connected to the host connector to isolate the first carrier.

10. The electronic device according to claim 9, wherein the isolation element is an inductor.

11. A host, configured to control an apparatus, and comprising:
a controller, configured to generate a control signal;
a signal transmission unit, electrically connected to the controller, to receive the control signal and generate a carrier to carry the control signal; and
a connector, configured to connect the apparatus, wherein the connector comprises at least one of a power pin and a ground pin to transmit the carrier.

12. The host according to claim 11, wherein the controller transmits the control signal to the signal transmission unit by using a communications protocol.

13. The host according to claim 12, wherein the communications protocol is an SMBUS communications protocol, an I2C communications protocol, or an SPI communications protocol.

14. The host according to claim 11, wherein the power pin is configured to supply power to the apparatus.

15. The host according to claim 11, wherein the signal transmission unit is a modulation/demodulation processing unit.

16. The host according to claim 11, wherein the connector is a fan connector, a universal serial bus (USB) connector, a serial advanced technology attachment (SATA) connector, an HDMI connector, a Display port connector, or a D-sub connector.

17. The host according to claim 11, wherein the control signal is a digital signal.

18. The host according to claim 11, further comprising an isolation element electrically connected to the connector to isolate the carrier.

19. The host according to claim 18, wherein the isolation element is an inductor.
